(19) United States
(12) Patent Application Publication
(10) Pub. No.: US 2024/0044984 A1
(43) Pub. Date: Feb. 8, 2024

(54) REMAINING LIFE DETERMINING SYSTEM FOR MOTOR

(71) Applicant: TOYOTA JIDOSHA KABUSHIKI KAISHA, Aichi-ken (JP)

(72) Inventors: Takuya HACHIYA, Toyota-shi (JP); Mikihito FUKAMI, Toyota-shi (JP); Tomonori OGURA, Toyota-shi (JP); Hiroshi INANO, Miyoshi-shi (JP); Hirotsugu IWAMOTO, Nissin-shi (JP); Kenji TANABE, Toyota-shi (JP)

(21) Appl. No.: 18/327,890

(22) Filed: Jun. 2, 2023

(30) Foreign Application Priority Data
Aug. 2, 2022 (JP) 2022-123147

(51) Int. Cl. G01R 31/34; G01R 27/16

(52) U.S. Cl. CPC G01R 31/34; G01R 27/16

(57) ABSTRACT

A controller for determining degradation of the motor, the controller includes a first acquisition unit for acquiring an impedance between the coil and the core, an estimation unit for estimating the total amount of heat input to the motor based on the magnitude of the impedance between the coil and the core, and a determination unit for determining the remaining life due to thermal degradation of the motor based on the total amount of heat input estimated by the estimation unit.

### CROSS-REFERENCE TO RELATED APPLICATION

This application claims priority to Japanese Patent Application No. 2022-123147 filed on Aug. 2, 2022, incorporated herein by reference in its entirety.

### BACKGROUND

### 1. Technical Field

The present disclosure relates to a system for determining a remaining life of a motor due to thermal deterioration.

### 2. Description of Related Art

Japanese Unexamined Patent Application Publication No. 2017-146252 (JP 2017-146252 A) describes a system for diagnosing a precursor such as peeling of an interface between an energized portion of an electric apparatus and a resin mold or cracking of the resin mold. In this system, the stress applied to the surface of the resin mold is measured by a stress measuring device using radiation light such as X-rays, and the stress applied to the surface of the resin mold and the function of the stress of the surface portion and the stress of the interface portion determined in advance by a test piece or the like are used to obtain the stress applied to the interface portion between the energized portion and the resin mold. Then, from the stress applied to the interface portion, the system determines considerable elapsed years.

WO 2011/074654 describes a method for predicting the remaining life of a bearing, which is configured to predict the remaining life of the bearing in response to fatigue of the bearing, without destroying the bearing. This remaining life prediction method is configured to detect an impedance of a load surface on which a load is applied, such as a raceway surface of an outer ring, a raceway surface of an inner ring, and a rolling surface of a rolling element, after use of the bearing, by an eddy current measuring device, and compare the detected impedance with an impedance before use of the bearing or an impedance of a portion other than the load surface to predict the remaining life of the bearing.

Japanese Unexamined Patent Application Publication No. 2011-007662 (JP 2011-007662 A) describes a remaining life diagnosis method configured to diagnose the remaining life of a control wiring of a power receiving and transforming facility without destroying the control wiring. In this remaining life diagnosis method, first, white light is irradiated to each of a new product and a deteriorated product (measurement target product) of the wiring, and the reflected light is spectrally analyzed. Then, the reflectance of each of the new product and the deteriorated product is obtained, and the reflectance difference between two predetermined wavelengths of the obtained reflectances is compared with each other to diagnose the remaining life based on the reflectance difference.

### SUMMARY

In order to diagnose the considerable elapsed years without destroying the electric apparatus, the diagnosis system described in JP 2017-146252 A measures the stress of the resin mold using radiation light such as X-rays, and based on the measurement result, determines the stress of the interface between the energized portion that is the inner portion of the resin mold and the resin mold. That is, a parameter correlated with the target portion among the parameters detectable from the outer surface of the electric apparatus is selected, and the deterioration of the target portion is determined by measuring the selected parameter.

Similarly, in the remaining life prediction method described in WO 2011/074654, the impedance of the component is measured by an eddy current measuring device from the outer surface of the bearing in order to determine the deterioration of the bearing, and in the remaining life diagnosis method described in JP 2011-007662 A, the outer surface of the wiring is irradiated with white light.

Therefore, there is a possibility that it is unable to determine the thermal deterioration of a member that is not necessarily correlated with parameters measurable from the outer surface of the motor, such as the covering material such as enamel covering the winding of the motor, an adhesive material such as varnish for bonding the winding and the core to which the winding is wound, etc.

The present disclosure has been made in view of the above technical problems, and an object of the present disclosure is to provide a remaining life determining system for a motor that is capable of determining a remaining life due to thermal deterioration of a member covering a winding of the motor or a member bonding a winding and a core.

In order to achieve the above object, the present disclosure relates to a remaining life determining system for a motor including a stator provided in an annular shape, a rotor disposed opposite to the stator, and a coil attached to one of a core of the stator and the rotor. The remaining life determining system includes a controller for determining deterioration of the motor. The controller is characterized by including: a first acquisition unit for acquiring an impedance between the coil and the core; an estimation unit for estimating a total amount of heat input to the motor, based on a magnitude of the impedance between the coil and the core; and a determination unit for determining a remaining life of the motor due to thermal deterioration based on the total amount of heat input that is estimated by the estimation unit.

In the present disclosure, the controller may further include a first database storing a relationship between a high temperature storage time during which the motor is exposed to a first predetermined temperature determined in advance and the magnitude of the impedance, and the estimation unit may estimate the total amount of heat input to the motor, based on the first acquisition unit and the first database.

In the present disclosure, the remaining life determining system may further include a covering material for covering the coil. The controller may further include a second database storing a relationship between the total amount of heat input to the motor and a tensile strength of the covering material. The determination unit may determine the remaining life of the motor due to the thermal deterioration based on the total amount of heat input that is estimated by the estimation unit and the second database.

In the present disclosure, the remaining life determining system may further include a measuring instrument including: a power source for applying a predetermined voltage to the coil and the core; a sensor for detecting a current flowing through the coil and the core; and a calculation unit for determining the impedance between the coil and the core based on a voltage applied by the power source and a current value detected by the sensor. The first acquisition unit may acquire the impedance between the coil and the core from the measuring instrument.

In the present disclosure, the predetermined voltage may include an alternating current voltage of a predetermined frequency determined in advance, and the calculation unit may obtain the impedance based on the alternating current voltage and a leakage current flowing between the coil and the core.

In the present disclosure, the controller may further include: a second acquisition unit that acquires a reflectance of a predetermined part determined in advance of the motor; and a third database storing a relationship between the reflectance, the high temperature storage time, and the number of thermal shocks that is the number of times of changing a temperature of the motor between a second predetermined temperature determined in advance and a third predetermined temperature. The first database may stores a relationship between the impedance, the high temperature storage time, and the number of thermal shocks. The estimation unit may be configured to estimate the total amount of heat input to the motor, based on the impedance acquired by the first acquisition unit, the reflectance acquired by the second acquisition unit, the first database, and the third database, and to estimate the number of thermal shocks of the motor. The determination unit may determine a remaining life of the motor due to a high-temperature stress based on the total amount of heat input that is estimated by the estimation unit, and a remaining life of the motor due to a thermal shock based on the number of thermal shocks estimated by the estimation unit.

In the present disclosure, the remaining life determining system may further include an adhesive material interposed between the coil and the core. The controller may further include a fourth database storing a relationship between the number of thermal shocks of the motor and shear stress of the adhesive material. The determination unit may determine the remaining life of the motor due to the thermal shock based on the number of thermal shocks estimated by the estimation unit and the fourth database.

In the present disclosure, at the time of measurement such as the case of obtaining an impedance from detection data such as a current value, or at the time of construction of a database in the case of determining the relationship between the impedance and the high temperature storage time, by determining data related to external factors such as measurement environment and measurement conditions by artificial intelligence, the accuracy of the correlation of the measurement value and the database may be improved.

According to the present disclosure, an impedance between a core of a stator or a rotor and a coil attached to the core is obtained, and the total amount of heat input to the motor is estimated based on the obtained impedance. Then, the remaining life of the motor due to the thermal deterioration is determined based on the estimated total amount of heat input. Therefore, since it is possible to determine the remaining life of the motor due to thermal deterioration including the member covering the coil, the adhesive material interposed between the core and the coil, and the like, without destroying the motor, the remaining life of the motor after market traveling can be determined, making it possible to reuse the motor for rebuild-and-reuse purposes and to replace the motor before the motor malfunctions.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic diagram for explaining an example of a remaining life determining system for a motor according to an embodiment of the present disclosure;

FIG. 2 is a graph showing the relationship between the high temperature storage time and the tensile strength of enamel;

FIG. 3 is a graph showing the rate of change in volume of varnish when the motor is exposed to a high temperature environment;

FIG. 4 is a schematic view showing a state in which the varnish is peeled off from the coil or the core by decreasing the volume of the varnish;

FIG. 5 is a diagram illustrating a relationship between an applied voltage and a leakage current when impedance is measured;

FIG. 6 is a graph showing a relationship between high-temperature storage time and capacitance;

FIG. 7 is a flowchart for explaining a determination flow of the remaining life determining system according to the embodiment of the present disclosure;

FIG. 8 is a schematic diagram for explaining another example of the remaining life determining system of the motor according to the embodiment of the present disclosure;

FIG. 9 is a map showing the relationship between capacitance, high temperature storage time, and number of thermal shocks;

FIG. 10 is a diagram showing a relationship between a high-temperature storage time and the number of thermal shocks when the capacitance is a predetermined value;

FIG. 11 is a map showing the relationship between reflectance, high temperature storage time, and number of thermal shocks;

FIG. 12 is a diagram showing a relationship between a high-temperature storage time and the number of thermal shocks when the reflectance is a predetermined value;

FIG. 13 is a diagram for explaining a means for estimating a high-temperature storage time and the number of thermal shocks based on FIGS. 10 and 12;

FIG. 14 shows the relationship between the number of thermal shocks and the shear stress of the varnish; and

FIG. 15 is a flowchart for explaining another determination flow of the remaining life determining system according to the embodiment of the present disclosure.

### DETAILED DESCRIPTION OF EMBODIMENTS

The disclosure will be explained on the basis of an embodiment shown in the figures. Note that the embodiments described below are merely examples of a case where the present disclosure is embodied, and are not intended to limit the present disclosure.

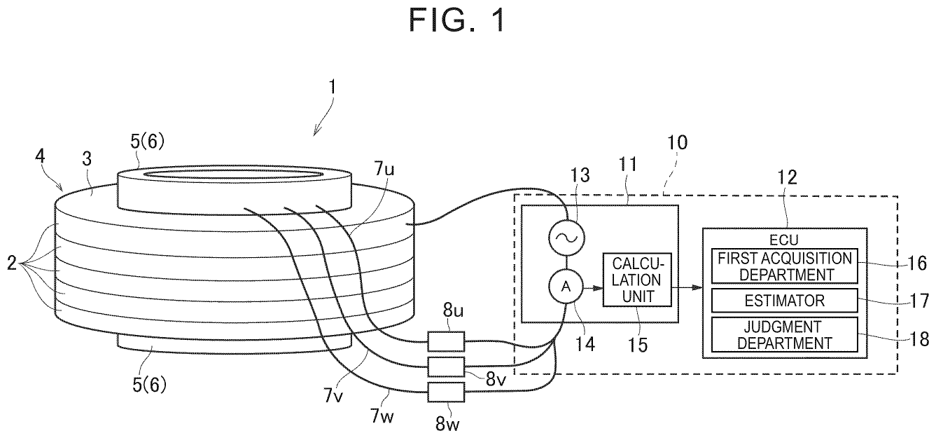

A motor according to an embodiment of the present disclosure includes a stator, a rotor, and a coil wound around at least one of the stator and the rotor. The motor may be a DC motor with a brush in which a coil is wound around a rotor. The motor may be an AC motor having a coil wound around the stator or a coil wound around each of the stator and the rotor. The motor is not limited to the radial gap type motor, and may be an axial gap type motor. FIG. 1 shows a three-phase AC motor provided as a driving force source of a conventional battery electric vehicle or hybrid electric vehicle. More specifically, an example of a stator 1 used in a permanent magnet synchronous motor is shown.

The stator 1 shown in FIG. 1 is formed by laminating an annular steel plate 2 in the axial direction in the same manner as the conventional stator. Each of the steel plates 2 includes a yoke portion 3 formed in an annular shape and a plurality of teeth (not shown) protruding toward the center of the yoke portion 3. Incidentally, the outer peripheral surface of each yoke portion 3, a mounting portion (not shown) protruding radially outward is formed. By fixing the attachment portion to a case (not shown), the yoke portions 3 are restrained in the axial direction. In this way, the plurality of steel plates 2 are stacked and integrated in the axial direction to form the core 4.

The plurality of teeth portions are formed at predetermined intervals in the circumferential direction of the yoke portion 3. The coil 5 is wound around the tooth portion. The coil 5 may be formed of a relatively thin copper wire having a circular cross-sectional shape. The coil 5 may be formed of a relatively thick copper wire having a rectangular cross-sectional shape. In FIG. 1, for convenience, only the coil end portion 6 protruding in the axial direction of the core 4 of the coil 5 is schematically shown.

The coil 5 is formed by contacting copper wires with each other. Therefore, each copper wire is covered with a covering material such as enamel to insulate between adjacent copper wires. In addition, an adhesive material such as a varnish is applied to the coil 5 in order to harden the copper wire or to bond the copper wire and the tooth portion. A power line 7u, 7v, 7w is connected to the U-phase, the V-phase, and the W-phase in the coil-end portion 6, and a terminal 8u, 8v, 8w is attached to an end portion of the power line 7u, 7v, 7w.

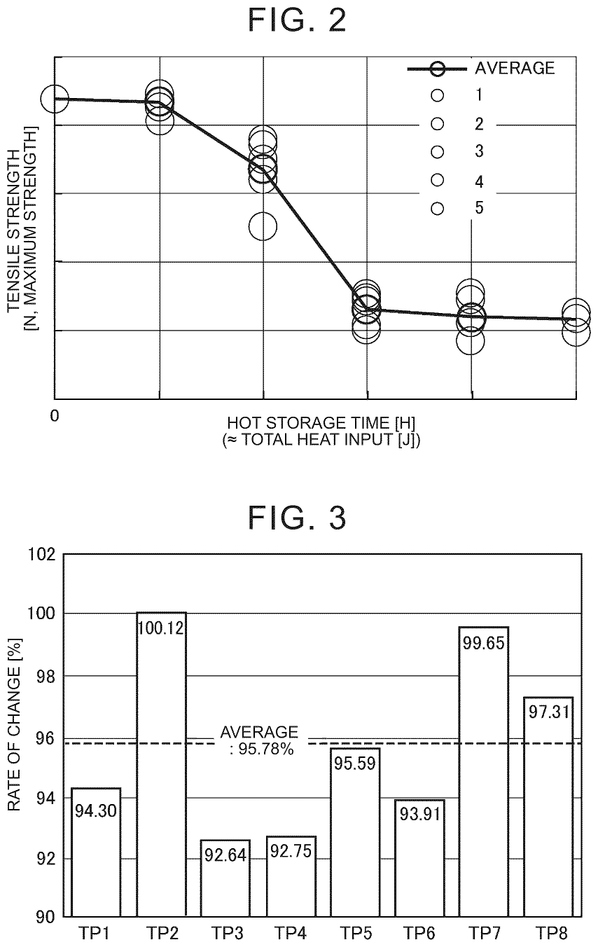

In the motor configured as described above, the temperature of the coil 5 increases due to copper loss or iron loss during driving, and thus the tensile strength of the enamel decreases. FIG. 2 shows experimental results of verifying the relationship between the time (high-temperature storage time) when the enamel is exposed to a high-temperature environment of a predetermined first predetermined temperature and the tensile strength of the enamel. The horizontal axis shows the high-temperature storage time, and the vertical axis shows the tensile strength of the enamel. Incidentally, verification was performed using five test pieces, the tensile strength of each test piece is plotted by “o”, the average value is shown by a line.

As shown in FIG. 2, it can be seen that the tensile strength of the enamel decreases as the high-temperature storage time increases. That is, the higher the total amount of heat input to the enamel, the lower the tensile strength of the enamel. Therefore, the total heat input amount that the tensile strength of the enamel is a predetermined value, the total heat input to the motor reaches the life of the motor. A database that maps the relationship between the tensile strength of the enamel and the high-temperature storage time shown in FIG. 2 corresponds to the “second database” in the embodiment of the present disclosure. This data base is stored in an ECU 12 to be described later. In the following description, this database is referred to as a tensile strength map.

On the other hand, when the motor is exposed to a high temperature environment of a predetermined temperature for a predetermined time, the volume of the varnish decreases. FIG. 3 shows experimental results of measuring the volume change rate (reduction rate) of the varnish when the motor is stored at high temperature for a predetermined time. Here, the test was performed using eight test pieces (TP). As shown in FIG. 3, it can be seen that the volume of the varnish decreases by an average of 4.22% when the motor is exposed to a high temperature environment for a predetermined period of time.

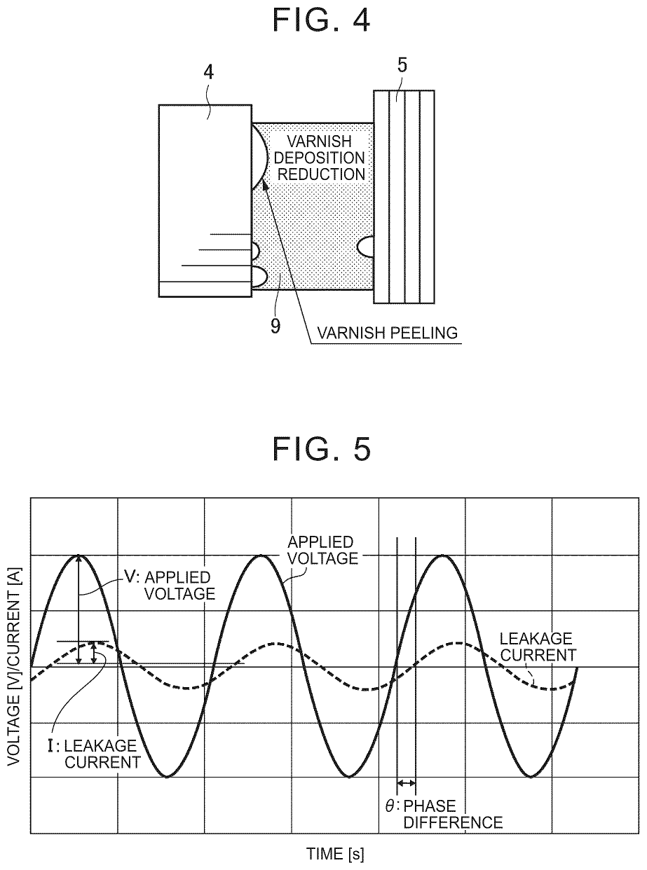

The distance between the coil 5 and the core 4 and the area facing the coil 5 and the core 4 are considered to be constant without being affected by the high-temperature storage time. On the other hand, when the volume of the varnish changes as described above, as shown in FIG. 4, a portion of the varnish 9 is peeled off from the coil 5 and the core 4, air is interposed in the peeled portion, the dielectric constant between the coil 5 and the core 4 is considered to change. That is, it is conceivable that the impedance (more specifically, the capacitance) between the coil 5 and the core 4 changes.

Therefore, the remaining life determining system of the motor according to the embodiment of the present disclosure is configured to estimate the total amount of heat input to the motor based on the impedance between the coil 5 and the core 4, and to determine the remaining life of the motor based on the total amount of heat input.

FIG. 1 shows an example of the remaining life determining system 10. The remaining life determining system 10 includes a LCR meter 11 for measuring the impedance between the coil 5 and the core 4, and an electronic control unit (hereinafter, referred to as an ECU) 12 for determining the remaining life of the motor from the measured value. Note that LCR meter 11 corresponds to the “measuring instrument” in the embodiment of the present disclosure, and ECU 12 corresponds to the “controllers” in the embodiment of the present disclosure.

LCR meter 11 includes an AC power supply 13 that applies an AC voltage to the coil 5 and the core 4, a current sensor 14 that detects a current (leakage current) flowing between the coil 5 and the core 4, and a calculation unit 15 that obtains an impedance such as an inductance, a capacitance, and a resistance of a target from the output voltage (applied voltage) and the current value. In other words, LCR meter 11 is connected to the coil 5 and the core 4. Based on the AC voltage applied between the coil 5 and the core 4 and the current value detected by the current sensor 14, the calculation unit 15 obtains an inductance, a capacitance, or a resistance. Here, the power line 7u, 7v, 7w is short-circuited so that the current between the coil 5 and the core 4 is measured. However, the current value between the power line connected to either phase and the core 4 may be measured, such as measuring the current value between the power line 7u connected to the U-phase and the core 4.

FIG. 5 shows an example of a current value detected by the current sensor 14 when an AC voltage is applied between the coil 5 and the core 4. In FIG. 5, the vertical axis represents the voltage value and the current value, and the horizontal axis represents the time. As shown in FIG. 5, a predetermined phase difference θ occurs between the AC voltage of a predetermined frequency and the current (leakage current) value detected by the current sensor 14. Therefore, the calculation unit 15 calculates the capacitance Cs based on the following Expression (1).

Cs=Z cos θ (1)

Here, Z is the ratio (V/I) of the maximum value V of the voltage and the maximum value I of the current.

ECU 12 is mainly composed of a microcomputer, and is configured to determine the remaining life of the motor based on inputted data and a data base such as a map stored in advance.

ECU 12 illustrated in FIG. 1 includes a first acquiring unit 16 that acquires capacitance Cs, an estimation unit 17 that estimates the total amount of heat input to the motor based on the capacitance Cs acquired by the first acquiring unit 16, and a determination unit 18 that determines the remaining life of the motor based on the total amount of heat input estimated by the estimation unit 17.

The first acquiring unit 16 is configured to acquire the capacitance Cs calculated by the calculation unit 15 in LCR meter 11.

The estimation unit 17 is configured to expose the motor to a high-temperature environment, measure the capacitance Cs at predetermined time intervals, and estimate the total heat input amount of the motor based on a data base in which the relation between the high-temperature storage time and the capacitance Cs is mapped. Specifically, the high-temperature storage time is obtained from the data base and the capacitance Cs acquired by the first acquiring unit 16, and the amount of heat corresponding to the high-temperature storage time is estimated as the total amount of heat input of the motor.

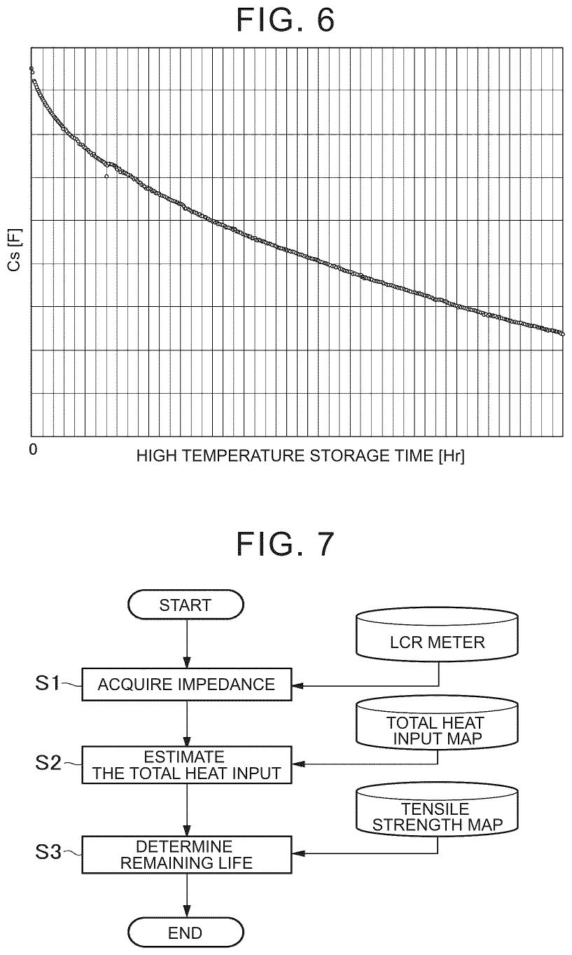

FIG. 6 shows an exemplary data base in which a capacitance Cs is taken on the vertical axis and a high-temperature storage period is taken on the horizontal axis. As shown in FIG. 6, the capacitance Cs decreases as the high-temperature storage period increases. Here, the total amount of heat input can be calculated by integrating the stored temperature and the stored time. That is, the high-temperature storage time and the total amount of heat input can be regarded as substantially the same. It should be noted that this database corresponds to the “first database” in the embodiment of the present disclosure, and in the following description, it is referred to as a total heat input amount map.

The determination unit 18 is configured to determine the remaining life of the motor from the total amount of heat input estimated by the estimation unit 17 and the tensile strength map. Specifically, the upper limit heat amount which is the upper limit value of the total heat input amount is determined from the tensile strength map and the allowable lower limit value of the tensile strength of the enamel, and the remaining life due to the thermal deterioration is determined based on the total heat input amount estimated by the estimation unit 17 with respect to the upper limit heat amount.

FIG. 7 illustrates an exemplary decision flow performed by ECU 12. In the embodiment shown in FIG. 7, first, the impedance (capacitance) is obtained from LCR meter 11 (step S1). Then, the total heat input amount of the motor is estimated by referring to the total heat input amount map (step S2). Subsequently, the remaining life of the motor is determined on the basis of the total heat input amount estimated in the step S2 and the tensile strength map (step S3), and the routine is temporarily ended.

By obtaining the capacitance between the coil 5 and the core 4 as described above, the total amount of heat input to the motor can be determined. Therefore, based on the tensile strength map showing the relationship between the total amount of heat input to the motor and the tensile strength of the enamel, it is possible to determine the remaining life due to thermal deterioration of the motor. Therefore, without destroying the motor, it is possible to determine the remaining life due to thermal deterioration of the motor including a member (enamel) covering the coil 5 and an adhesive material (varnish) interposed between the core 4 and the coil 5. Therefore, it is possible to determine the remaining life of the motor after running on the market, to reuse the motor for rebuild and reuse, or to replace the motor before the motor fails.

Further, in the market, in addition to the high-temperature stress caused by the temperature rise state is maintained by copper loss or iron loss of the motor, the temperature of the motor is changed repeatedly to high temperature and low temperature the motor is thermally deteriorated by thermal shock.

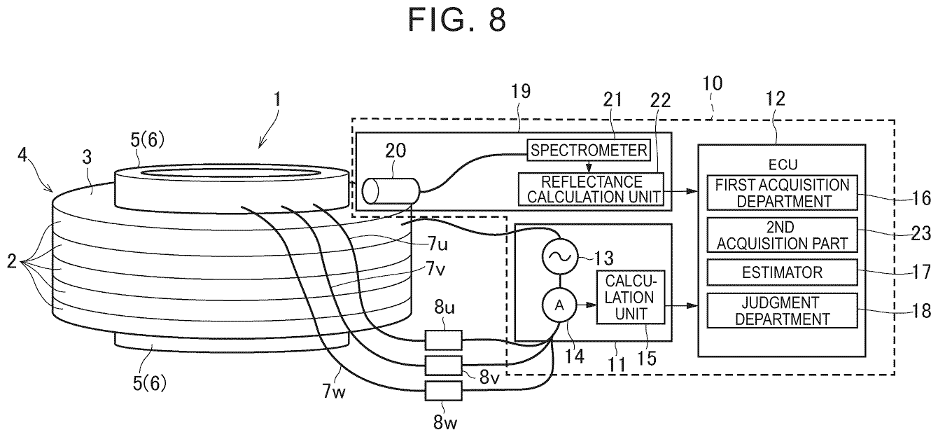

Therefore, the remaining life determining system according to the embodiment of the present disclosure is configured to determine the thermal deterioration of the motor by separating the thermal deterioration (high-temperature stress) caused by being exposed to the high-temperature environment and the thermal deterioration (thermal shock) caused by the temperature change. FIG. 8 is a schematic diagram for explaining the remaining life determining system, and includes an optical spectrum analyzer 19 in addition to the example shown in FIG. 1.

The optical spectrum analyzer 19 is configured by a probe 20 that irradiates a predetermined portion of the motor with white light and receives the reflected light, a spectroscope 21 that spectrally decomposes the reflected intensity of the reflected light received by the probe 20 for each wavelength, and a reflectance calculation unit 22 that obtains the reflectance of the reflected light. The optical spectrum analyzer 19 can be configured in the same manner as a conventional reflectance calculator. In the example illustrated in FIG. 8, the reflectance of the coil end portion 6 is calculated, but it may be configured to calculate the reflectance of any surface of the member integrated with the motor.

In addition to the functions shown in FIG. 1, ECU 12 shown in FIG. 8 further includes a second acquiring unit 23 that acquires the reflectance calculated by the optical spectrum analyzer 19. Further, ECU 12 shown in FIG. 8 includes a database that maps the relationship between the thermal load obtained by adding the number of thermal shocks to the high-temperature storage time and the capacitance, and a database that maps the relationship between the high-temperature storage time, the number of thermal shocks, and the reflectance. ECU 12 is configured to estimate the total heat input to the motor from the databases and the number of thermal shocks of the motor. Here, the number of thermal shocks is the number of times that the process of raising the temperature of the motor from a predetermined second predetermined temperature to a third predetermined temperature and then lowering the temperature from the third predetermined temperature to the second predetermined temperature is set as one cycle. The third predetermined temperature is set to be lower than the first predetermined temperature.

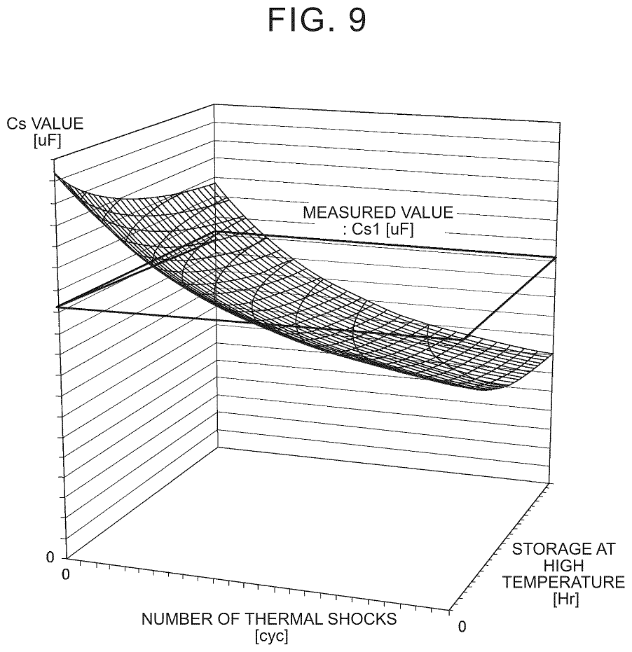

FIG. 9 is an example of a capacitance map constructed by previously experimentally measuring relationships between high temperature storage time, number of thermal shocks, and capacitance. The number of thermal shocks is taken on the X-axis, the high temperature storage time is taken on the Y-axis, and the capacitance is taken on the Z-axis. As shown in FIG. 9, the capacitance decreases as the high-temperature storage time increases, and the capacitance decreases as the number of thermal shocks increases. The capacitance map is a map for estimating the total amount of heat input to the motor based on the impedance between the coil 5 and the core 4. Therefore, the capacitance map corresponds to the “first database” in the embodiment of the present disclosure.

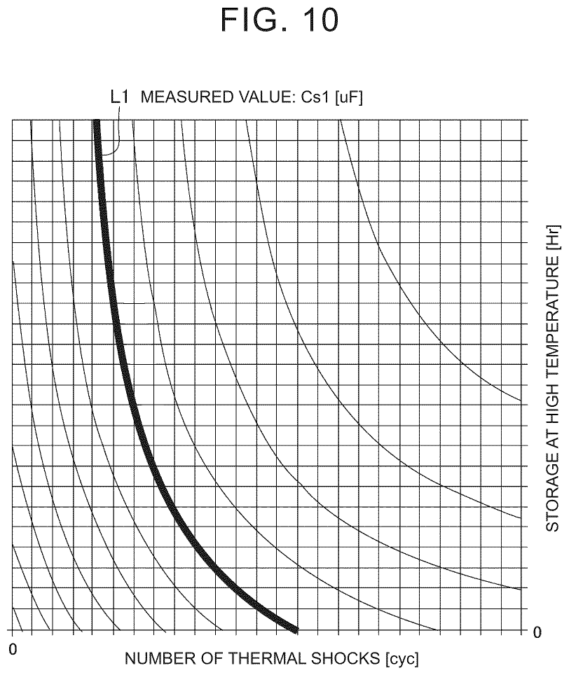

Therefore, when the capacitance calculated by the calculation unit 15 is Cs1 the predetermined value, the high-temperature storage period and the number of thermal shocks are correlated as shown by the line L1 in FIG. 10. In FIG. 10, the number of thermal shocks is taken on the horizontal axis and the high-temperature storage time is taken on the vertical axis.

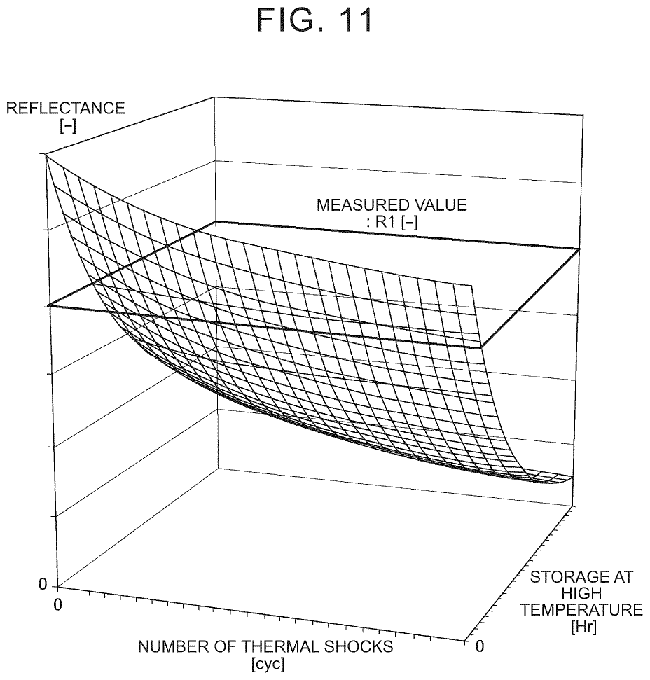

FIG. 11 is an example of a reflectance map constructed by previously experimentally measuring the relationship between the high-temperature storage time, the number of thermal shocks, and the reflectance of a predetermined wavelength. The number of thermal shocks is taken on the X-axis, the high temperature storage time is taken on the Y-axis, and the capacitance is taken on the Z-axis. As shown in FIG. 11, the reflectance decreases as the high-temperature storage time increases, and the reflectance decreases as the number of thermal shocks increases. The reflectance map corresponds to the “third database” in the embodiment of the present disclosure.

Here, the amount of decrease in reflectance with respect to the high-temperature storage time is larger than the amount of decrease in capacitance with respect to the high-temperature storage time, and the amount of decrease in reflectance with respect to the number of thermal shocks is smaller than the amount of decrease in capacitance with respect to the number of thermal shocks. That is, the sensitivity of the reflectance to the high-temperature storage time is better than the sensitivity of the capacitance to the high-temperature storage time. In contrast, it can be seen that the sensitivity of capacitance to high temperature storage time is better than the sensitivity of reflectance to high temperature storage time.

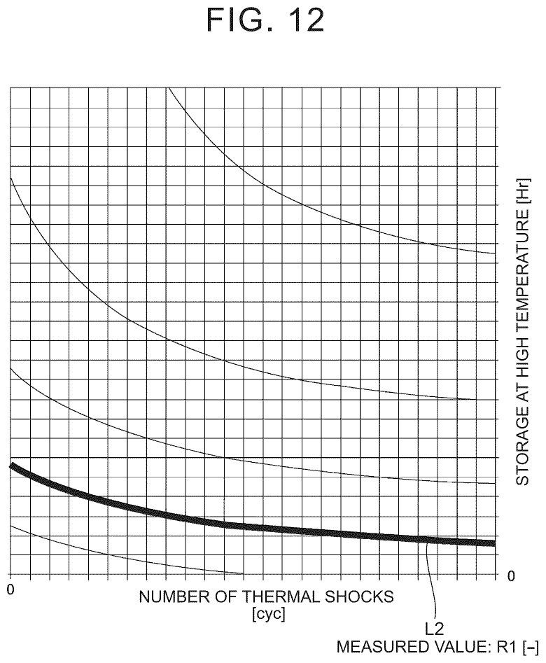

Therefore, when the reflectance calculated by the reflectance calculation unit 22 is R1 the predetermined value, the high-temperature storage period and the number of thermal shocks are correlated as shown by the line L2 in FIG. 12. In FIG. 12, the number of thermal shocks is taken on the horizontal axis and the high-temperature storage time is taken on the vertical axis.

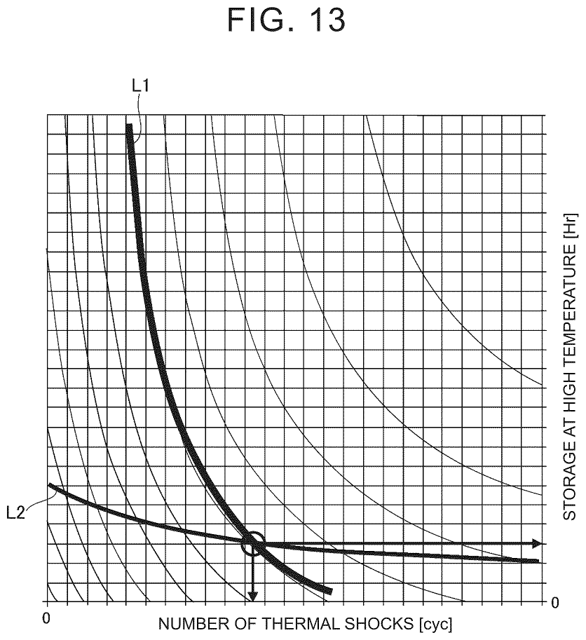

By calculating the capacitance and the reflectance as shown in FIGS. 10 and 12, it is possible to extract the relationship between the high-temperature storage time and the number of thermal shocks. Therefore, the estimation unit 17 can estimate the high-temperature storage period and the number of thermal shocks by extracting the intersection of the line L1 and the line L2 as shown in FIG. 13.

Similarly to the above-described example, the determination unit 18 is configured to determine the remaining life of the motor from the total amount of heat input estimated by the estimation unit 17 and the tensile strength map. Specifically, the determination unit 18 is configured to determine an upper limit heat amount which is an upper limit value of the total heat input amount from the tensile strength map and the allowable lower limit value of the tensile strength of the enamel, and to determine the remaining life due to the thermal deterioration based on the total heat input amount estimated by the estimation unit 17 with respect to the upper limit heat amount. More specifically, the determination unit 18 is configured to determine the remaining life due to the high-temperature stress.

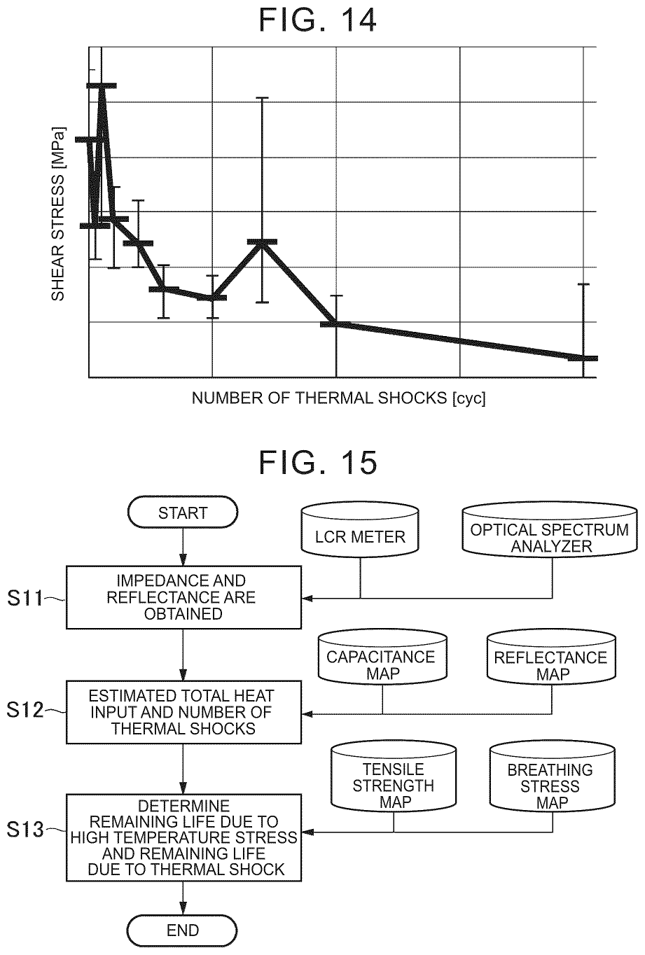

Further, as shown in the shear stress map in FIG. 14, the number of thermal shocks increases, and the adhesive strength (shear stress) of the varnish decreases. Therefore, the shear stress map is stored in ECU 12 in advance, and the number of thermal shocks is estimated by the estimation unit 17, whereby the remaining life due to the thermal shock of the motor can be determined based on the estimated number of thermal shocks and the shear stress map of the varnish.

Specifically, the determination unit 18 determines the upper limit number of times that is the upper limit value of the number of thermal shocks from the shear stress map and the allowable lower limit value of the shear stress of the varnish, and the determination unit 18 is configured to determine the remaining life due to the thermal deterioration based on the number of thermal shocks estimated by the estimation unit 17 with respect to the upper limit number. More specifically, the determination unit 18 is configured to determine the remaining life due to the thermal shock. The shear stress map corresponds to the “fourth database” in the embodiment of the present disclosure.

FIG. 15 is a flowchart illustrating a determination process performed by ECU 12. In the embodiment shown in FIG. 15, first, the impedance (capacitance) is acquired from LCR meter 11, and the reflectance is acquired from the optical spectrum analyzer 19 (step S11). Then, referring to the capacitance map and the reflectance map, the total heat input (high temperature storage time) and the number of thermal shocks of the motor are estimated (step S12). Subsequently, based on the total amount of heat input estimated by the step S12, the remaining life due to the high-temperature stress of the motor based on the tensile strength map, and the number of thermal shocks and the shear stress map, the remaining life due to the thermal shock of the motor is determined (step S13), and the routine is temporarily ended.

By obtaining the capacitance between the coil 5 and the core 4 as described above, the total amount of heat input to the motor can be determined. Therefore, based on the tensile strength map showing the relationship between the total amount of heat input to the motor and the tensile strength of the enamel, it is possible to determine the remaining life due to the high-temperature stress of the motor. Further, by acquiring the reflectance, the number of thermal shocks of the motor can be determined. Based on the shear stress map showing the relationship between the number of thermal shocks of the motor and the adhesive strength (shear stress) of the varnish, the remaining life due to the thermal shock of the motor can be determined. Therefore, in addition to the same effects as in the above-described example, the degree of thermal deterioration can be determined by distinguishing the remaining life due to the high-temperature stress from the remaining life due to the number of thermal shocks. In other words, the degree of deterioration of the varnish and the enamel can be individually determined.

What is claimed is:

1. A remaining life determining system for a motor including a stator provided in an annular shape, a rotor disposed opposite to the stator, and a coil attached to one of a core of the stator and the rotor, the remaining life determining system comprising a controller for determining deterioration of the motor, wherein the controller includes:
a first acquisition unit for acquiring an impedance between the coil and the core;
an estimation unit for estimating a total amount of heat input to the motor, based on a magnitude of the impedance between the coil and the core; and
a determination unit for determining a remaining life of the motor due to thermal deterioration based on the total amount of heat input that is estimated by the estimation unit.

2. The remaining life determining system according to claim 1, wherein
the controller further includes a first database storing a relationship between a high temperature storage time during which the motor is exposed to a first predetermined temperature determined in advance and the magnitude of the impedance, and
the estimation unit estimates the total amount of heat input to the motor, based on the first acquisition unit and the first database.

3. The remaining life determining system according to claim 1, further comprising a covering material for covering the coil, wherein
the controller further includes a second database storing a relationship between the total amount of heat input to the motor and a tensile strength of the covering material, and
the determination unit determines the remaining life of the motor due to the thermal deterioration based on the total amount of heat input that is estimated by the estimation unit and the second database.

4. The remaining life determining system according to claim 1, further comprising a measuring instrument including:
a power source for applying a predetermined voltage to the coil and the core;
a sensor for detecting a current flowing through the coil and the core; and
a calculation unit for determining the impedance between the coil and the core based on a voltage applied by the power source and a current value detected by the sensor, wherein the first acquisition unit acquires the impedance between the coil and the core from the measuring instrument.

5. The remaining life determining system according to claim 4, wherein
the predetermined voltage includes an alternating current voltage of a predetermined frequency determined in advance, and
the calculation unit obtains the impedance based on the alternating current voltage and a leakage current flowing between the coil and the core.

6. The remaining life determining system according to claim 2, wherein:
the controller further includes
a second acquisition unit that acquires a reflectance of a predetermined part determined in advance of the motor, and
a third database storing a relationship between the reflectance, the high temperature storage time, and the number of thermal shocks that is the number of times of changing a temperature of the motor between a second predetermined temperature determined in advance and a third predetermined temperature;
the first database stores a relationship between the impedance, the high temperature storage time, and the number of thermal shocks;
the estimation unit is configured to estimate the total amount of heat input to the motor, based on the impedance acquired by the first acquisition unit, the reflectance acquired by the second acquisition unit, the first database, and the third database, and to estimate the number of thermal shocks of the motor; and
the determination unit determines a remaining life of the motor due to a high-temperature stress based on the total amount of heat input that is estimated by the estimation unit, and a remaining life of the motor due to a thermal shock based on the number of thermal shocks estimated by the estimation unit.

7. The remaining life determining system according to claim 6, further comprising an adhesive material interposed between the coil and the core, wherein
the controller further includes a fourth database storing a relationship between the number of thermal shocks of the motor and shear stress of the adhesive material, and
the determination unit determines the remaining life of the motor due to the thermal shock based on the number of thermal shocks estimated by the estimation unit and the fourth database.
